(19) United States
(12) Patent Application Publication
(10) Pub. No.: US 2013/0099856 A1
(43) Pub. Date: Apr. 25, 2013

(54) Methods and Circuits for Achieving Rational Fractional Drive Currents in Circuits Employing FinFET Devices

(71) Applicant: David S. Doman, Austin, TX (US)

(72) Inventor: David S. Doman, Austin, TX (US)

(73) Assignee: GLOBALFOUNDRIES INC., Grand Cayman (KY)

(21) Appl. No.: 13/279,608

(22) Filed: Oct. 24, 2011

(51) Int. Cl. H01L 27/105

(52) U.S. Cl. 327/566

(57) ABSTRACT

Disclosed herein are various methods and circuits for achieving rational fractional drive strengths in circuits employing FinFET devices. In one example, the device disclosed herein includes a semiconducting substrate, a first plurality of FinFET transistors formed in and above the substrate, wherein each of the first plurality of FinFET transistors is adapted to produce an individual drive current, and wherein the first plurality of FinFET transistors are configured in a series circuit. The drive current resulting from the series circuit is a rational fraction of the individual drive current.

### BACKGROUND OF THE INVENTION

1. Field of the Invention

Generally, the present disclosure generally relates to the manufacturing of sophisticated semiconductor devices, and, more specifically, to various methods and circuits for achieving rational fractional drive strengths in circuits employing FinFET devices.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit elements that substantially determine performance of the integrated circuits. One illustrative example of a simple, prior art FET 20 is schematically depicted in FIG. 1. The FET 20 is a planar device that is formed in an active area of a semiconducting substrate 10. The active area is defined by an illustrative isolation structure 11. The FET 20 includes a source region 18A, a drain region 18B, a channel region 13 that is positioned between the source region 18A and the drain region 18B, and a gate electrode 14 positioned above the channel region 13. The gate electrode 14 is separated from the channel region 13 by a gate insulation layer 12. Sidewall spacers 16 are typically formed adjacent the gate electrode 14. Current flow through the FET 20 is controlled by controlling the voltage applied to the gate electrode 14. If there is no voltage applied to the gate electrode 14, then there is no current flow through the device (ignoring undesirable leakage currents which are relatively small). However, when an appropriate voltage is applied to the gate electrode 14, the channel region 13 becomes conductive, and electrical current is permitted to flow between the source region 18A and the drain region 18B through the conductive channel region 13.

FIGS. 2A-2B are partial views of an illustrative embodiment of a simple FinFET device 30, wherein an isolation structure and layers of insulating material are not shown so as to facilitate the present discussion. In contrast to a FET 20, which has a planar structure, a FinFET device 30 is a 3-dimensional structure. The FinFET 30 includes a source region 32S, a drain region 32D, a plurality of fins 36 that are cut from the substrate 10, a gate electrode 34 and a gate insulation layer 38. FIG. 2B is a cross-sectional view of the FinFET 30 taken as indicated in FIG. 2A. As depicted, in the illustrative FinFET 30, the plurality of generally vertically positioned fins 36 are active areas that are defined in the substrate 10. As shown in FIG. 2B, the gate electrode 34 encloses both sides and an upper surface of the fins 36 to form a tri-gate structure so as to use a channel having a 3-dimensional structure instead of a planar structure like that in the FET 20. Unlike the planar FET 20, in the FinFET device 30, a channel, in the form of a fin 36, is formed perpendicular to a surface of the semiconducting substrate 10 so as to reduce the physical size of the semiconductor device. Moreover, the height of this channel, i.e., the fin 36, is, for all practical production purposes fixed. That is, trying to produce multiple FinFET devices with varying channel or fin “heights” would not be practical as it would, at a minimum, result in severe topography changes which leads to a whole host of problems when trying to manufacture FinFET devices 30 on a commercial production scale.

In designing digital circuits, one parameter that is very important is the desired drive current produced by individual transistors (FETs and/or FinFETs) and the overall drive current needed or produced by a given circuit arrangement. In circuits involving planar FETs, device designers can produce FETs that generate virtually desired fractional level of drive current. That is, for planar FETs the drive current of the FET may be readily adjusted to virtually any value by simply changing the gate width of the FET. For example, if a designer desires a FET with ½ strength drive current, then the gate width of a standard FET with an integer drive strength of 1 is simply reduced by half. Similarly, if twice the drive strength of a standard FET is required, then the gate width of the FET is doubled. Of course, increasing the gate width of an FET consumes more plot space, but the ability to produce FETs with desired fractional drive currents gives device designers great flexibility in designing integrated circuits. Many digital and analog circuits are based upon designs that involve fractional drive current strengths. However, as discussed above, with FinFETs, the channel width is fixed by the height of the fin. Thus, as noted above, it is simply not practical to make FinFETs having differing channel heights in a modern, high-volume semiconductor manufacturing environment to produce FinFETs with fractional drive currents using such a technique.

The present disclosure is directed to various methods and circuits for achieving fractional drive strengths in circuits employing FinFET devices.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods and circuits for achieving rational fractional drive strengths in circuits employing FinFET devices. In one example, the device disclosed herein includes a semiconducting substrate, a first plurality of FinFET transistors formed in and above the substrate, wherein each of the first plurality of FinFET transistors is adapted to produce an individual drive current, and wherein the first plurality of FinFET transistors are configured in a series circuit. The drive current resulting from the series circuit is a rational fraction of the individual drive current.

In another illustrative example, a device disclosed herein includes a semiconducting substrate, a first and a second plurality of FinFET transistors formed in and above the substrate, wherein each of the first and second plurality of FinFET transistors is adapted to produce an individual drive current. In this example, the first plurality of FinFET transistors are configured in a series circuit and the second plurality of FinFET transistors are configured in a parallel circuit, wherein the series circuit is operatively coupled to the parallel circuit. A drive current resulting from the combined series circuit and the parallel circuit is a rational fraction of the individual drive current.

### BRIEF DESCRIPTION OF THE DRAWINGS

The disclosure may be understood by reference to the following description taken in conjunction with the accompanying drawings, in which like reference numerals identify like elements, and in which:

FIG. 1 is a schematic depiction of one illustrative embodiment of a simple prior art FET device;

FIGS. 2A-2B are schematic depictions of one illustrative embodiment of a simple prior art FinFET device; and

FIGS. 3A-3F depict various illustrative methods and circuits for achieving rational fractional drive strengths in circuits employing FinFET devices.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

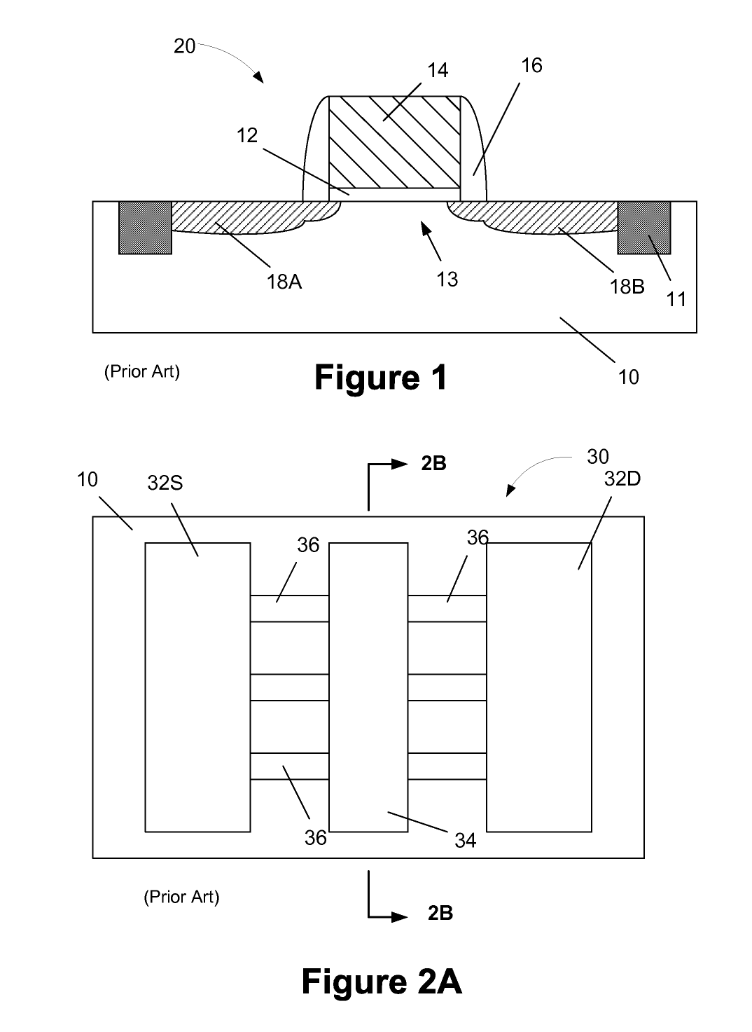

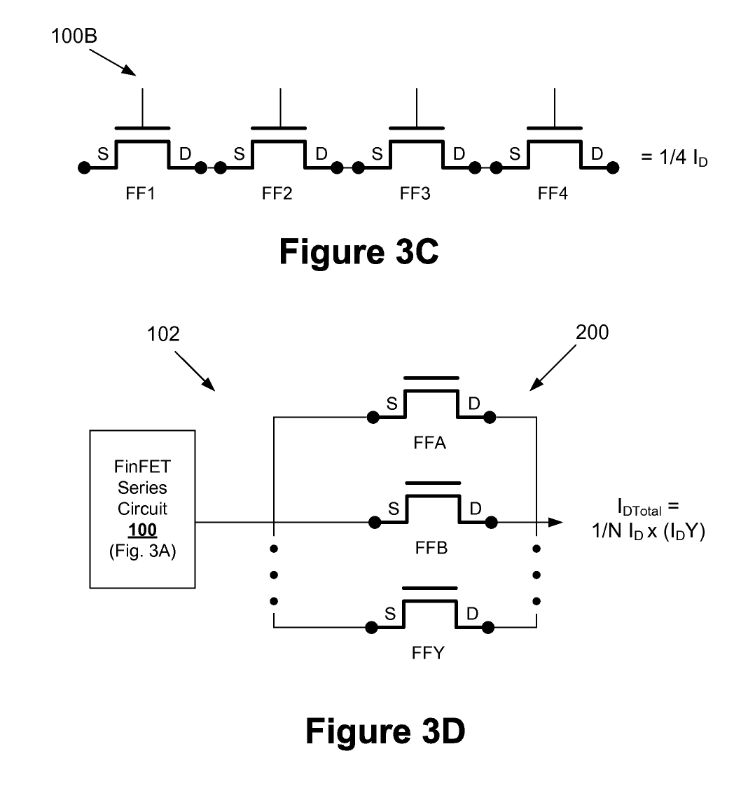

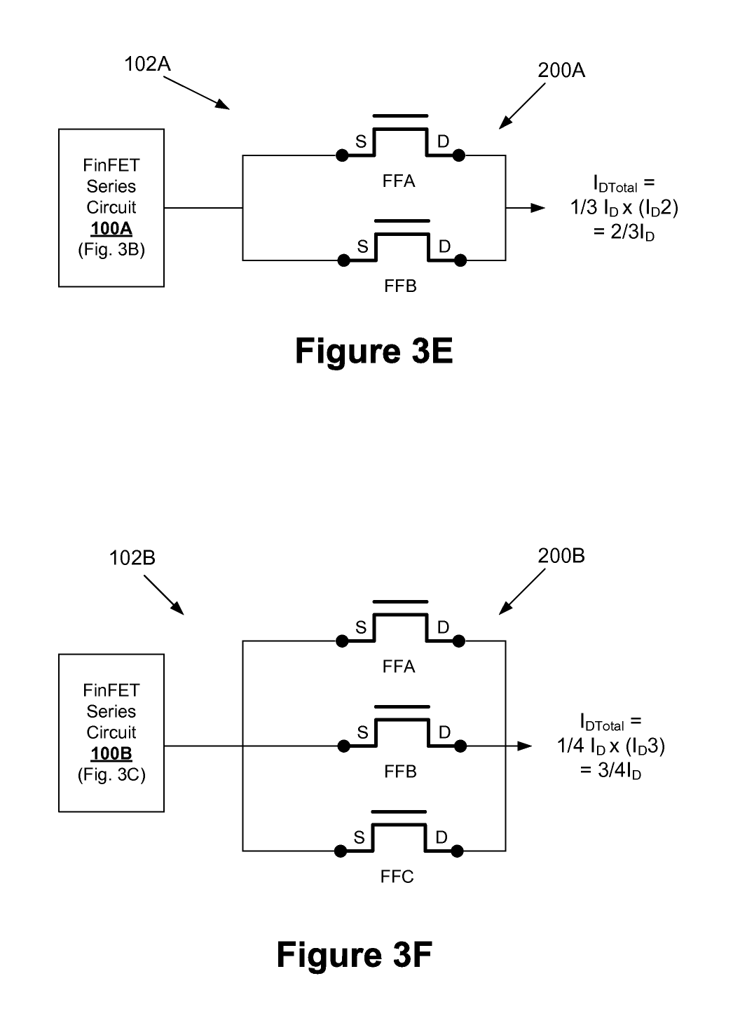

The present disclosure is directed to various methods and circuits for achieving rational fractional drive strengths in circuits employing FinFET devices. As will be readily apparent to those skilled in the art upon a complete reading of the present application, the inventions disclosed herein are readily applicable to a variety of devices, including, but not limited to, ASICs, logic devices, memory devices, analog devices, etc. With reference to FIGS. 3A-3F various illustrative embodiments of the methods and devices disclosed herein will now be described in more detail. To the extent that the same reference numbers are used in both FIGS. 1 and 2 and FIGS. 3A-3F, the previous description of those structures applies equally to FIGS. 3A-3F.

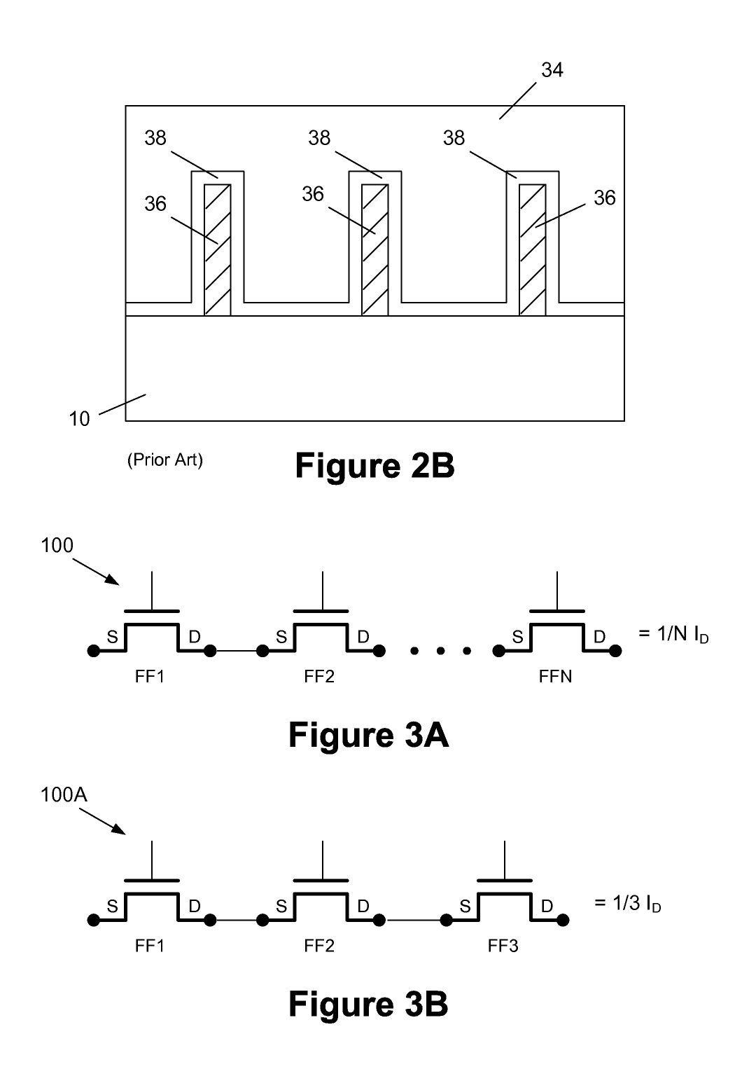

The present invention is directed to the use of FinFET transistors in designing integrated circuits. Any type of FinFET transistor that employs a vertically oriented fin structure may be employed as describe herein. The particular details of how such FinFET transistors are configured and manufactured are well known to those skilled in the art, and thus such details will not be repeated herein. In one example, the illustrative FinFET 30 depicted in FIG. 2 may be employed in the circuits described herein. Thus, the particular details of a FinFET device and the manner in which such a FinFET transistor is made should not be considered a limitation of the present invention.

FIG. 3A depicts an illustrative circuit 100 that comprises a plurality of FinFET transistors (FF1, FF2 . . . FFN) arranged in series. In this embodiment, the drain (“D”) of each FinFET is conductively coupled to the source (“S”) of each adjacent FinFET. Any number of FinFETs may be arranged in such a series configuration. The gate (“G”) of the FinFETs in the series would be connected together.

For a given FinFET design, the FinFET will produce an individual drive current (“I_{D}”). Each of the FinFETs in the circuit 100 are each of the same design, i.e, they all have the same fin height, the same target doping levels, etc. Thus, considered individually, each of the FinFETs (FF1, FF2 . . . FFN) will produce the same individual drive current (I_{D}). However, when the FinFETs are arranged in series, as shown in FIG. 3A, the total drive current (“I_{DTotal}”) produced by the circuit 100 is the individual drive current (I_{D}) divided by the number of FinFETs in the circuit 100. Stated mathematically, for a circuit that contains 1-N FinFETs arranged in series, the total drive current such a circuit is:

I_{DTotal}=1/NI_{D}

For example, FIG. 3B depicts an illustrative circuit 100A that comprises three FinFET transistors (FF1, FF2, and FF3) arranged in series. The total drive current (“I_{DTotal}”) produced by the circuit 100A is ⅓ of the individual drive current (I_{D}) of the FinFETs in the circuit 100A, i.e., ⅓ I_{D}. FIG. 3C depicts another illustrative circuit 100B that comprises four FinFET transistors (FF1, FF2, FF3 and FF4) arranged in series. The total drive current (“I_{DTotal}”) produced by the circuit 100B is ¼ of the individual drive current (I_{D}) of the FinFETs in the circuit 100A, i.e., ¼ I_{D}.

By using this unique series arrangement of FinFETs, circuits that employ FinFET transistors may be created so as to produce fractional drive currents which will be very beneficial in designing circuits that employ such FinFET transistors. Given that the number of FinFETs that may be arranged in a series circuit 100 is, for practical purposes, virtually limitless, the fractional drive current resulting from such a series circuit 100 may be adjusted to virtually any desired fractional drive current level.

FIGS. 3D-3F depict various circuits 102 that may be employed to achieve FinFET circuits with fractional drive current. FIG. 3D depicts an illustrative parallel configured FinFET circuit 200 that is operatively coupled to the schematically depicted series configured circuit 100 shown in FIG. 3A. The parallel configured FinFET circuit 200 comprises a plurality of FinFET transistors (FFA, FFB . . . FFY) arranged in parallel. In this embodiment, the drain (“D”) of each of the FinFETs are conductively coupled to one another, and the source (“S”) of each FinFETs are conductively coupled to one another. Any number of FinFETs may be arranged in such a parallel configuration. The gates (“G”) of each of the FinFETs in this parallel arrangement are connected in common. As noted above, for a given FinFET design, each of the FinFETs in the parallel circuit 200 will produce an individual drive current (“I_{D}”). Each of the FinFETs in the circuit 200 are each of the same design, i.e, they all have the same fin height, target doping levels, etc. Thus, considered individually, each of the FinFETs (FFA, FFB . . . FFY) will produce the same individual drive current (I_{D}). However, looking solely at the parallel configured circuit 200, when the FinFETs are arranged in parallel, as shown in FIG. 3D, the total drive current (“I_{DTotal}”) produced by the circuit 200 is the individual drive current (I_{D}) multiplied by the number of FinFETs in the parallel configured circuit 200. Stated mathematically, for a parallel configured circuit 200 that contains A-Y FinFETs arranged in parallel, the total drive current such a circuit is:

I_{DTotal}=YI_{D}

This characteristic of parallel configured FinFET circuits 200 may be used in combination with the series configured FinFET circuits 100 to achieve fractional drive currents from FinFET circuits in an efficient manner. As note previously, the total drive current (“I_{DTotal}”) produced by the series configure circuit 100 is the individual drive current (I_{D}) divided by the number of FinFETs in the circuit 100, i.e., 1/N I_{D}. When the drive current (1/N I_{D}) from the series configured circuit 100 (with “N” FinFETs) is input to the parallel configure FinFET circuit 200 (with “Y” FinFETS), the resulting total drive current (“I_{DTotal}”) produced by the combined overall circuit 102 may be expressed mathematically as follows:

I_{DTotal}=1/NI_{D}×YI_{D}

For example, FIG. 3E depicts an illustrative combined circuit 102A that comprises the series circuit 100A operatively coupled to a parallel configured FinFET circuit 200A. The series circuit 100A is comprised of three FinFET transistors (FF1, FF2, and FF3) arranged in series, as shown in FIG. 3B. The parallel configured FinFET circuit 200A is comprised of two FinFET transistors (FFA and FFB) arranged in parallel. The total drive current (“I_{DTotal}”) produced by the combined overall circuit 102A is ⅔ I_{D}−(⅓ I_{D}×2 I_{D}).

FIG. 3F depicts yet another illustrative combined circuit 102B that comprises the series circuit 100B operatively coupled to a parallel configured FinFET circuit 200B. The series circuit 100B is comprised of four FinFET transistors (FF1, FF2, FF3 and FF4) arranged in series, as shown in FIG. 3C. The parallel configured FinFET circuit 200B is comprised of three FinFET transistors (FFA, FFB and FFC) arranged in parallel. The total drive current (“I_{DTotal}”) produced by the combined overall circuit 102B is ¾ I_{D}−(¼ I_{D}×3I_{D}).

As those skilled in the art will recognize after a complete reading of the present application, the circuit arrangements depicted in the drawings are only examples and the present inventions may be employed in a variety of circuits having a variety of configurations. For example, the combined circuits 102, 102A and 102B were described and discussed in the illustrative context where the series circuit 100, 100A, 100B were positioned upstream of the parallel circuits 200, 200A, 200B. In practice, the depicted positions of the parallel circuits and the series circuits could be reversed and the resulting drive current from the overall combined circuit would be the same.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising:
a semiconducting substrate; and
a first plurality of FinFET transistors formed in and above said substrate, each of said first plurality of FinFET transistors being adapted to produce an individual drive current, said first plurality of FinFET transistors being configured in a series circuit, wherein a drive current resulting from said series circuit is a rational fraction of said individual drive current.

2. The device of claim 1, wherein a drain of each of said first plurality of FinFET transistors is conductively coupled to a source of an adjacent FinFET transistor in said series circuit and a gate of each of said first plurality of FinFET transistors are commonly connected.

3. The device of claim 1, wherein each of said first plurality of FinFET transistors comprise at least one fin having a height, and wherein the height of each of the at least one fin on each of the first plurality of FinFET transistors is the same.

4. The device of claim 1, wherein said first plurality of FinFET transistors comprises three FinFET transistors configured in said series circuit, wherein a drive current resulting from said series circuit is approximately one-third of said individual drive current.

5. The device of claim 1, wherein said first plurality of FinFET transistors comprises four FinFET transistors configured in said series circuit, wherein a drive current resulting from said series circuit is approximately one-fourth of said individual drive current.

6. The device of claim 1, wherein said fraction of said individual drive current is a value that is equal to the individual drive current divided by the number of FinFET transistors in said series circuit.

7. The device of claim 1, further comprising a second plurality of FinFET transistors formed in and above said substrate, each of said second plurality of FinFET transistors being adapted to produce said individual drive current, said second plurality of FinFET transistors being configured in a parallel circuit, wherein said series circuit is operatively coupled to said parallel circuit, and wherein a drive current resulting from said combined series circuit and said parallel circuit is a rational fraction of said individual drive current.

8. The device of claim 7, wherein each of said second plurality of FinFET transistors comprise at least one fin having a height, and wherein the height of each of the at least one fin on each of the second plurality of FinFET transistors is the same.

9. The device of claim 7, wherein a drain of each of said second plurality of FinFET transistors in said parallel circuit is conductively coupled to one another and a source of each of said second plurality of FinFET transistors in said parallel circuit is conductively coupled to one another and a gate of each of said second plurality of FinFET transistors are connected in common.

10. A device, comprising:
a semiconducting substrate; and
a first and a second plurality of FinFET transistors formed in and above said substrate, each of said first and second plurality of FinFET transistors being adapted to produce an individual drive current, said first plurality of FinFET transistors being configured in a series circuit, said second plurality of FinFET transistors being configured in a parallel circuit, wherein said series circuit is operatively coupled to said parallel circuit, and wherein a drive current resulting from said combined series circuit and said parallel circuit is a rational fraction of said individual drive current.

11. The device of claim 10, wherein said fraction of said individual drive current is a value that is equal to the individual drive current divided by the number of FinFET transistors in said series circuit multiplied by the number of FinFET transistors in said parallel circuit.
